(19) United States
(12) Patent Application Publication
(10) Pub. No.: US 2016/0225299 A1
(43) Pub. Date: Aug. 4, 2016

(54) APPARATUS FOR OBSCURING A SENSING ELEMENT PROXIMATE A PRINTED GRAPHIC

(71) Applicant: 3M INNOVATIVE PROPERTIES COMPANY, Saint Paul, MN (US)

(72) Inventors: Philip E Watson, Mountain View, CA (US); Scott E Brigham, Maplewood, MN (US); William J Bryan, Mahtomedi, MN (US); John C Schultz, Afton, MN (US)

(73) Assignee: 3M INNOVATIVE PROPERTIES COMPANY, St. Paul, MN (US)

(21) Appl. No.: 15/025,293

(22) PCT Filed: Sep. 26, 2014
(86) PCT No.: PCT/US2014/057700

§ 371 Date: Mar. 28, 2016

Related U.S. Application Data
(60) Provisional application No. 61/884,336, filed on Sep. 30, 2013.

(51) Int. Cl. G09F 27/00; H03K 17/945

(52) U.S. Cl. CPC G09F 27/005; H03K 17/945

(57) ABSTRACT

A system for obscuring a sensing device associated with a printed graphic while preserving the device's sensing functionally by use of a piece of perforated film printed to match the printed graphic.

### BACKGROUND

Two common forms of signage in retail and public-space settings include digital displays on the one hand, and printed graphics on the other. Digital displays are commonly based on LCDs, projectors, or other electronically addressable display systems, and provide an image by electrically addressing the display system.

Although digital displays can provide changing images and video, the high initial cost layout for purchasing the equipment and the onerous operational support required to provide power, video signals, and frequently updated content to the display detracts from advantages associated with their technical capabilities. Printed graphics have multiple advantages as compared with digital displays: they are typically much lower cost than digital displays, they may be very flat and conformable to surfaces, and they require no external power supply. Disadvantages include the limitations of the use experience—it is typically a non-interactive experience that can be easily ignored.

### SUMMARY

A way of obscuring from human view interactivity cards associated with a printed graphic film. Particularly sensor-type cards may be advantageously hidden within a printed graphic sign in such a way that they may continue to effectively function as sensors by applying over the sensor card a piece of perforated film printed to match the underlying graphic sign. A first embodiment includes involves the application of the matching perforated film onto a first major surface of the sensor card, then the second major surface of the sensor card (the side opposite to the first major surface), is adhered to the printed graphic sign. In such an embodiment, the perforated film does not overlap, or minimally overlaps, the sensor card. In another embodiment, the perforated film is designed to overlap the sensor card and an adhesive is used around the overlapping portions to secure the perforated film to the printed graphic sign so as to envelope the sensor card to the front surface of the printed graphic sign. Methods of applying the perforated film are also described.

### BRIEF DESCRIPTION OF FIGURES

FIG. 1 is drawing showing one exemplary embodiment of interactivity cards in conjunction with printed advertisements.

FIG. 2 is a simplified schematic of a sensor card.

FIG. 3 is a simplified schematic of a response card.

FIG. 4 is a drawing of the exterior of an interactivity card.

FIG. 5 is a drawing of a portion of a printed graphic with an interactivity card that is included on the face of the printed graphic obscured using perforated film.

FIG. 6 is a blow-up of the perforated film used in FIG. 5.

FIG. 7 is a drawing of a cross section of a stack that includes an interactivity card and a perforated film to obscure from view the interactivity card as attached to a graphic film.

### DETAILED DESCRIPTION

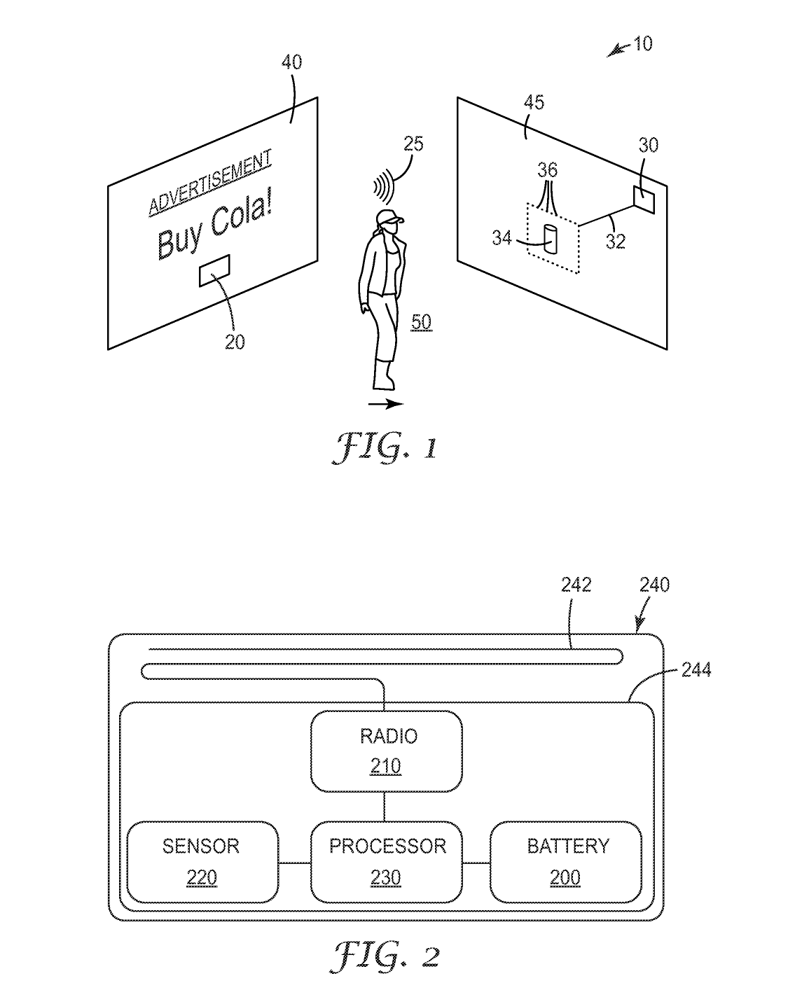

FIG. 1 shows how interactivity cards may be used in conjunction with content, such as advertising content. Advertising scenario 10 has person 50 walking past two banner advertisements (40 and 45). The advertising content associated with the first banner advertisement 40 highlights a product for person 50. Sensor card 20 is embedded within banner advertisement 40, and is configured to sense the presence of person 50. Sensor 20 is wirelessly communicatively coupled to response card 30, which is associated with banner advertisement 45. Upon sensing the presence of person 50, radio signal 25 is generated from an on-board radio associated with sensor card 20. A corresponding radio associated with response card 30 receives radio signal 25 and initiates an activity associated with it. In the embodiment shown in FIG. 1, the activity involves energizing LED light array 36 electrically coupled to response card 30 via conductor 32. The lights surround product 34, in this case a can of cola. As person 50 walks between signs, the two signs working in concert may provide a stronger impression for the person than would signs that do not have any interactivity associated with them.

Banner content 40 and 45 may comprise traditional print-type advertising content. It could also comprise any other type of suitable content. For example, content 40 and 45 could relate to direction-type navigational content, or instructions, etc. Such content is typically printed on a film of some kind, such as a PVC-based web, then hung either indoors or outdoors. In some embodiments, either the sensor card or the response card need not be expressly associated with some piece of content. For example, sensor card 20 could be located discreetly in proximity to banner advertisement 45, for example hung on a wall or a ceiling. In such a scenario, banner advertisement 40 need not even exist. Conversely, the response component need not be strictly associated with a banner advertisement, either. For example, the LED array 34 could be associated with a 3D model of a can of cola, and the can itself would be illuminated as the example response.

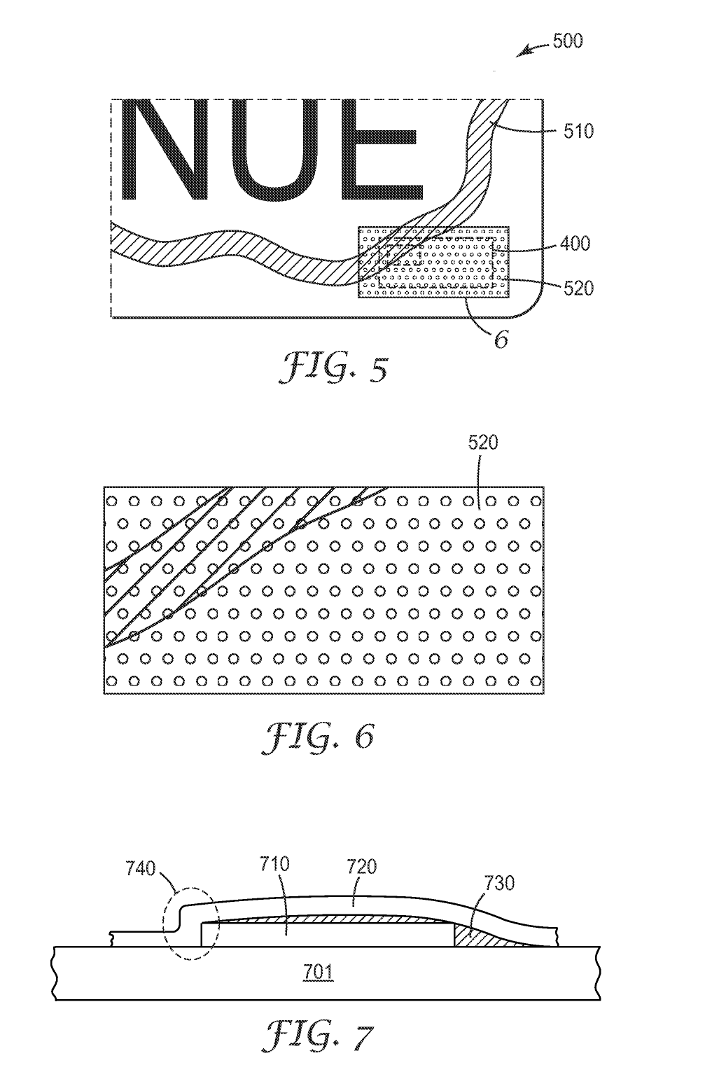

The interactivity cards themselves are thin cards having circuitry that is further described below. They are designed to be small and discreet, and easy to operate. In a preferred embodiment, they are actually incorporated onto or around the printed content itself. For example, in the case of the sensor card 20, this might mean adhering the sensor card to the back side of the banner advertisement 40, with a discreet hole cut into the substrate to accommodate the sensor of sensor card 40. Another embodiment, shown later with respect to FIG. 6, has the interactivity card placed on the face side of the banner content, but then obscured with a perforated film printed to match the content it covers. In such an embodiment, the interactivity card may be adhesive backed, and be adhered directly to the face of the banner content. The perforations allow the sensor to carry out its sensing operation in some embodiments.

The sensor card includes a sensor component designed to sense an environmental property of interest. Such a property may be the presence of an object (typically of size from about the size of a human child to that of a vehicle), the movement of an object (and direction), the movement of the sensor itself, or the contact made between the sensor and a conductive object, etc. Any suitable sensor may be employed in the sensor card. Example sensor technology includes photovoltaic sensors, motion sensors, capacitive sensors, touch sensors, acoustic sensors, or temperature sensors. Additionally, the sensor may be an NFC (Near-Field-Communications)-based sensor that identifies the presence of a compatible card, such as a properly enabled store loyalty card. The sensor may additionally be a sensor that identifies the presence of a WiFi, Bluetooth, or other RF signature (for example, from a person's cellular phone device) that indicates a person's presence proximate a device.

The response card includes an action element designed to engage upon a signal from the sensor card indicative of a sensed activity. The action element may be anything that may change state based on signals provided from a processor on the response card. For example, the action element may be an array of LED lights, or a motor that activates a mechanical process, or a speaker system that plays a sound. The action element may be included in the housing of the response card, or it may be off-card but communicatively coupled to the card via conductors (as shown in FIG. 1), or wirelessly. The action element may also be an input to a digital device such as a media player connected to an LCD or projector, where the signal from the response card initiates a change in content state of the media player. Additionally, the action element may be coupled to the lighting system of the environment, causing the state of ambient illumination to change (for example, flashing). The action element may also be a machine intended to change the ambience of the setting, such as a fog machine or a fountain that may be activated by the response card's output signal. In some cases, the response card may be programmed such that not every signal results in the same action; for example a random number generator on the response card's processor may be used in an algorithm that selects activating a lighting element, a sound element, both, or neither. Further, the response itself may vary based on signals received from the sensor card. For example, the signals from the sensor card may activate a different response during the day or during the night. In another embodiment, the response card is programmed to know the date or time of day, and may vary the response based on these parameters (for example, associating a first activity (e.g., motion) with daylight, and another, second activity (e.g., motion combined with artificial lighting), with nighttime).

The interactivity cards are communicatively coupled via a wireless link. This wireless link is provided by a wireless communications module included in both the sensor card and the response card. In a preferred embodiment, this link is a radio link that implements a wireless radio communications protocol, such as 802.11x or ANT or Bluetooth™ However, other wireless communications approaches are possible, for example infrared, audio, infrasonic, ultrasonic, and the like.

FIG. 2 shows a schematic of sensor card 240. In one embodiment, sensor card 240 has electrical components mounted on a thin, flexible printed circuit board substrate 244. Materials suitable for circuit board substrate 244 include FR-4, polyimide, PET, PEN, PEI FEP and other thin, preferably flexible substrate materials. A wireless communications module, in this case radio 210, is communicatively coupled, via the printed circuit board substrate 244, to processor 230, which is in turn communicatively coupled to sensor 220 and electrically coupled to battery 200.

Radio 210 communicates with other interactivity cards, particularly paired response cards. Radio 210 implements a proprietary or known communications protocol, such as the Bluetooth™ LE protocol, ANT protocol, IEEE 802.15.4, or any other suitable low-power radio communication protocol. The communication may be at 900 MHz, 2.4 GHz, or another appropriate radio frequency. Example electronic communication chips are the Nordic Semiconductor nRF51422 ANT™ System on Chip, the Nordic Semiconductor nRF24AP2 Series, the Texas Instruments CC2570, the Nordic Semiconductor and the Nordic Semiconductor nRF51822 Bluetooth® low energy System on Chip.

Processor 240 can be one that is integrated on the same chip as the radio, such as the Nordic Semiconductor nRF51422 described above which includes the ANT™ radio and an ARM® Cortex™ MO 32-bit processor. It could also comprise a separate microcontroller such as a Microchip PIC or Texas Instruments MSP430 that interfaces to the radio chip through a standard interface such as SPI, IIC, or a UART.

Communicatively coupled to processor 240 is sensor 220. There may be more than one sensor coupled to processor 240, as part of sensor card 240, though only one is shown with respect to FIG. 2. Further, the sensor components may be physically included as part of sensor card 240, or they may be located off-card and tethered via conductors to processor 230.

Sensor 220 in one embodiment comprises a proximity sensor operating via optical sensing or capacitive sensing. For example, an optical proximity sensor may comprise a flat, flexible photovoltaic device with an optional optical management layer. Other possible low-power sensor types, such as photoconductive, photoresistive may be used. In all of these cases, polymeric forms of the sensor are preferred to maintain the flexible nature of the solution and potential compatibility with all-printed solutions. In preferred embodiments, sensor 220 is able to detect the presence and/or motion of human-sized (adult or child) objects or vehicles.

Sensor 220 may also be a passive sensor which is sensitive to touch, presence of a cellular device and the like. Sensor 220 may also be an active sensor with low powered emission of radio, acoustic or optical energy to enhance the detection of nearby objects or the detection of a change in nearby objects.

Battery 200 comprises a thin, flexible battery. Battery 200 may be a non-rechargeable battery that has sufficient power for the lifetime of the interactivity card. In another embodiment, battery 200 is replaceable, preferably lasting one week or longer. Battery 200 may also be rechargeable. Battery 200 is preferably a thin cell that will allow for minimal distortion of a banner advertisement if positioned behind or in front of the banner. In one embodiment, a suitable battery includes the 3.7 volt, 3000mAh JA-0545135P by Galvani, which is a credit card sized thin battery.

Antenna 242 may be disposed on or off of substrate 244. It is shown in FIG. 2 as extending off of substrate 244. If other types of communications modules are used instead of radio 210, the antenna may not be required. For example, in one embodiment instead the communications module comprises an infra-red communications module instead of a radio. In another embodiment, the communications module comprises drive circuitry to provide electrical communication with the one or more additional modules via an electrically conductive path, such as a wire, printed conductor or the like.

FIG. 3 shows a schematic of response card 240R. Componentry included is similar to that which is shown with regard to sensor card 240 in FIG. 2, except that instead of a sensor the response card includes action element 221. Radio 210R receives communications from radio 210. Processor 230R analyzes the communications, and then may initiate activity associated with action element 221. For example, if action element 221 comprises an array of LED lights, as is shown in the example associated with FIG. 1, then processor may activate the LEDs, which may be traditional lights, or they may be used for other purposes (such as communications—ie, the LEDs could be IR, UV, optical pulsing, etc. to facilitate remote device communication).

Action element 221 is shown as physically part of response card 240R, but it may in other embodiments be located elsewhere but tethered to processor 230R via conductors, as is shown in the embodiment associated with FIG. 1.

Action element 221 may comprise LED lights, piezo-electric motors, speakers, electroactive polymers, chemical emissive devices (that is, odor emitters, phase change materials, or any device that may be activated via processor 220R.

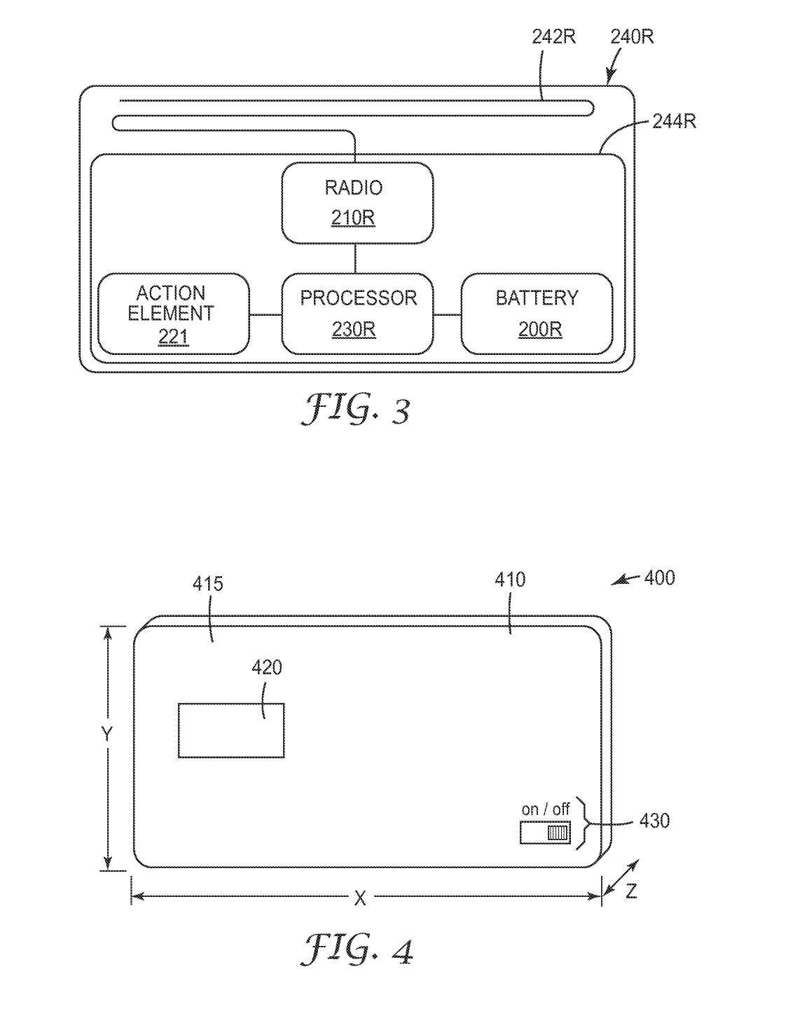

FIG. 4 shows a schematic of an example exterior housing of an interactivity card (either a sensor card or a receive card). The housing may be a thin, flexible plastic film. The thickness (Z axis) is in one embodiment less than 5 mm thick, and preferably less than 2 mm thick. It is flexible enough that it may be deformed to a radius of less than 152 mm, and preferably less than about 50 mm. The Y-dimension and X-dimension in one embodiment comprise 60×90 mm with a 50×50 mm battery on the board, or 30×67 mm with a 28×28 mm battery on the board. On/off switch 430 switches the interactivity card on or off. It may be a hard switch that actually breaks the power circuit included within the interactivity card, or it may be a soft switch that tells the interactivity card to go into a sleep mode. I/O area 420 accommodates either the sensor component (if a sensor card) or the activity component (if a response card). Of course, other embodiments are possible here, particularly if sensor or activity modules are tethered to the interactivity card. The shading 415 on interactivity card 400 signifies the presence of adhesive on the surface of the card. Using an adhesive is one possible way of mounting the interactivity card to a surface. Suitable adhesives include pressure sensitive adhesives such as 3M's VHB adhesives, hot-melt adhesives, and other commercially available adhesive systems. The use of removable and repositionable pressure-sensitive adhesives may allow simplicity of installation.

FIG. 5 shows an exemplary embodiment of a portion of a printed graphic sign 500. Printed graphic sign 500 may be any type of printed graphic sign. Graphic element 510 is shown extending over an area of the printed graphic sign. Sensor card 400 has been adhered to the face of printed graphic sign 500. Perforated film piece 520 has been printed to match an underlying area of the printed graphic sign, and has then been adhered to a sub-area of the printed graphic sign where the graphic element matches. Perforated film piece 520 thus encapsulates sensor card 400, allowing it to sense environmental variables through the perforations, but being very discreet. By encapsulate, it is meant that the surface of sensor 400 is covered; it is not strictly necessary that the film piece 520 overlap sensor 520 in each dimension (though such overlap may be desirable and is within the scope of this disclosure).

One appropriate perforated film to use as perforated film piece 520 is available from 3M Company of St. Paul, Minn., under the trade name “Perforated Window Graphic Film.” The perforated film piece in one embodiment isn't a separate piece—it is instead an area of the graphic sign which has been cut on demand, for example with a Summa cutter, in which case the perforated film piece 520 would be an integral part of the printed graphic 500.

Rather than a physically perforated film, a visually opaque but optically, acoustically, or thermally transparent film piece 520 or portion of the sign 500 could be used with a sensor 220 that was sensitive to IR, UV, etc. wavelengths, audio signal and/or the presence of thermal objects, for example, people.

Once constructed, the sensor card 520 may be adhered to the face of the graphic sign 500 using conventional pressure sensitive adhesive film and a laminating hand-roller application techniques. The pressure-sensitive adhesive may be applied to the sensor card as part of the manufacturing process prior to installation on the graphic. The adhesive may be a permanent adhesive or facilitate removability. The graphic element 520 is placed on top of the graphic sign 500 so as to closely match the underlying sub-area of the graphic sign 500. Other application processes may also be used, including starting with an adhesive-backed piece of printed perforated film, then adhering the sensor card to the back side (adhesive containing) of the perforated film piece first, with the film piece extending beyond (overlapping) the edges of the sensor card. The film/sensor combination is then applied to the graphic sign 500, with the overlapping adhesive edges holding the sensor and film piece to the graphic sign 500.

Interactivity cards may be manufactured by installing the above-mentioned components onto a flexible circuit board, using known techniques. Interactivity cards may be installed by adhering or otherwise fastening a sensor card within an area proximate a graphic sign, and adhering or otherwise fastening a response card in an area proximate the sensor card (and within range of the radios). The interactivity cards may then be switched “on” and thus paired, as is described below. They are then may be ready for action, in some embodiments without the further need for technical configuration or analysis.

FIG. 6 shows a further drawing of perforated film piece 520. The perforated film piece may be based on a 1 to 40 mil thick film, preferably less than 5 mils thick and more preferably 2 mils or less in thickness. The perforated film may be printed using conventional processes such as aqueous based inkjet printing, eco-solvent inkjet printing, solvent inkjet printing, UV inkjet printing, screen printing, offset printing, dye sublimation, and the like.

FIG. 7 is an illustration of the cross section of the stack that includes the graphic film 701, the sensor 710, and the perforated film piece 720. The degree to which the perforated film piece 720 assumes the topography of the underlying sensor/graphic film substrate will be a function of installation parameters. A looser application process may result in areas 730, which may be adhesive filled, or may just be air gaps. A tighter conformance is show in area 740, where the applicator has taken special care to bond the perforated film piece 720 to two sides of the sensor card and the graphic film surface. The perforations or related features may be modified, for example, to be made more or less dense, in the regions with sharp corners to better conform to the underlying material or provide a smoother surface.

In one embodiment, the perforated film is applied by first determining a sub-area of the underlying graphic where the sensor card might be placed such that it may effectively function as a sensor. For example, in large signs that extend vertically a great distance, it may be advantageous to locate the sensor card nearest pedestrian traffic (if it is pedestrians the sensor is intended to sense). Next, a sub-area of the underlying graphic may be selected. A piece of perforated film is then printed to match the sub-area. Alternatively, the printed graphic may exist pre-printed and then be tailored, by hand, to a specific size through the use of scissors. Yet further, it is possible to have a piece of film (non-perforated) that matches a sub-area of the underlying graphic, then it may be perforated as a further step.

Once the perforated film piece is ready, it may be applied in a direct, non-overlapping manner to a first major surface of the sensor card, then the second, opposite major surface of the sensor card adhered to the underlying graphic positioned so as to match the sub-area of the underlying graphic and reduce visual notice. Alternatively, the perforated film piece may overlap the sensor card, and in such case the perforated film, if adhesive backed, may be used to envelope the sensor card and adhere the edges of the perforated film piece to the underlying graphic. Preferably the sensor is positioned with respect to the perforated film piece so as to allow for sensing activities.

The perforations may vary in size and density to accommodate the sensing functionalities.

### Wireless Communication Between Cards; Pairing

In one embodiment, one sensor card is paired with one response card. Using the ANT radio protocol, ANT's pairing mechanism is used as follows. The sensor card, which is the ANT master, has a 16-bit device number that is unique amongst the sensor cards being used in the local installation. This 16-bit number can be individually programmed when the card is manufactured, or in the case of the Nordic Semiconductor nRF51422, the 16 least significant bits of the ARM processor's unique device ID can be used. When a sensor card is not currently paired with an activity card, it will set its pairing bit in its ANT Device Type. This information is transmitted as part of the sensor card's radio message. A response card, when it is not currently paired with a sensor card, will pair with any sensor card whose radio message it receives, if that sensor card has its pairing bit set. After it has paired, it sends a response message to its sensor card to indicate that the sensor card has been paired. The sensor card will then clear its pairing bit. The pairing state (paired or unpaired) is stored in nonvolatile memory so cards will keep their pairing state through power cycles or battery changes. Because paired sensor boards have their pairing bit cleared, the possibility that a new activity card will accidently pair with an already paired sensor card is eliminated. In addition, the ANT protocol can use radio signal strength as part of the pairing process, so an activity card will pair with the sensor card that has the strongest radio signal. By placing the two cards to be paired in close proximity (e.g., side by side on a table) this reduces the possibility that the activity card will accidently pair with an already installed sensor card, or another sensor card that is nearby and active, but that is not yet paired.

In another embodiment, using the ANT shard channel feature, one sensor card can be paired with up to 255 or up to 65535 response cards.

In another embodiment, using an ANT radio that supports multiple channels, such as the Nordic Semiconductor nRF51422 that supports up to 8 channels, one response card can pair with multiple sensor cards, one for each channel that is supported.

1. A system for obscuring from human view a sensor on the face of a printed graphic element, comprising:
a printed graphic comprising a plurality of sub-areas;
a sensor component having an area;
a perforated film piece printed to match at least one sub-area of the printed graphic;
and wherein the perforated film piece is disposed in front of the sensor component in an area associated with one of the plurality of sub-areas that matches the perforated piece.

2. The system of claim 1, wherein the perforated film piece extends beyond the area of the sensor component, and wherein at least some portions of the portions that extend beyond the area are adhered to the printed graphic, encapsulating the sensor component between the printed graphic and the perforated film piece.

3. The system of claim 1, wherein the perforated film piece does not extend beyond the area of the sensor component.

4. The system of claim 3, wherein the sensor has a first and second major side, and wherein the perforated film piece is coupled to a first major side of the sensor, and wherein the second major side of the sensor is coupled to the printed graphic.

5. The system of claim 4, wherein ‘coupled to’ comprises adhered.

6. The system of claim 5, wherein adhered comprises the use of a pressure sensitive adhesive.

7. The system of claim 1, wherein the perforated film piece has a plurality of regions, and wherein some of the regions have different perforation densities than others.
